(19) United States
(12) Patent Application Publication
(10) Pub. No.: US 2008/0048274 A1
(43) Pub. Date: Feb. 28, 2008

(54) Semiconductor device including a gate electrode of lower electrical resistance and method of manufacturing the same

(75) Inventors: Jung-Hun Seo, Suwon-si (KR); Hyun-Young Kim, Seoul (KR); Jin-Gi Hong, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/878,096

(22) Filed: Jul. 20, 2007

(30) Foreign Application Priority Data
Jul. 28, 2006 (KR) 10-2006-0071375

(51) Int. Cl. H01L 29/78; H01L 21/4763

(52) U.S. Cl. 257/411; 438/592; 257/E29.255; 257/E21.495

(57) ABSTRACT

A semiconductor device may include a gate insulating layer on a semiconductor substrate, a polysilicon layer doped with impurities on the gate insulating layer, an interface reaction preventing layer on the polysilicon layer, a barrier layer on the interface reaction preventing layer, and a conductive metal layer on the barrier layer. The interface reaction preventing layer may reduce or prevent the occurrence of a chemical interfacial reaction with the barrier layer, and the barrier layer may reduce or prevent the diffusion of impurities doped to the polysilicon layer. The interface reaction preventing layer may include a metal-rich metal silicide having a metal mole fraction greater than a silicon mole fraction, so that the interface reaction preventing layer may reduce or prevent the dissociation of the barrier layer at higher temperatures. Thus, a barrier characteristic of a poly-metal gate electrode may be improved and surface agglomerations may be reduced or prevented.

### PRIORITY STATEMENT

This application claims priority under 35 U.S.C. § 119 to Korean Patent Application No. 10-2006-0071375, filed on Jul. 28, 2006 in the Korean Intellectual Property Office (KIPO), the entire contents of which are incorporated herein by reference.

### BACKGROUND

1. Technical Field

Example embodiments relate to a semiconductor device including a gate electrode (e.g., poly-metal gate electrode) having a lower electrical resistance and/or an improved barrier characteristic and a method of manufacturing the same.

2. Description of the Related Art

Research for reducing the electrical resistance of a gate electrode of a semiconductor device is being conducted in response to increased integration so as to operate the semiconductor device at higher speeds. A conventional gate electrode (e.g., a metal gate electrode) may include a metal layer (e.g., a higher conductivity metal layer) formed on a gate insulating layer to achieve higher conductivity. For example, an aluminum layer formed on a gate insulating layer may be used as a gate electrode for a semiconductor device. However, the higher conductivity metal layer may be sensitive to heat, thus resulting in a metal gate electrode with lower heat resistance. Consequently, the metal gate electrode may not be suitable for a subsequent self-alignment structure, because the self-alignment structure may require a thermal treatment at a relatively high temperature, wherein the gate electrode may function as a mask pattern while forming the self-alignment structure.

To improve the lower heat resistance of the metal gate electrode, a polysilicon layer doped with impurities may be used as a gate electrode (e.g., a polysilicon gate electrode) for a semiconductor device. Consequently, the polysilicon gate electrode may be more suitable for the self-alignment structure because of a higher heat resistance of the polysilicon layer. In addition, the polysilicon layer may be formed on a gate oxide layer at an earlier stage of a manufacturing process of the semiconductor device to reduce or prevent contamination of the gate oxide layer. However, the polysilicon gate electrode may have a relatively high electrical resistance. The polysilicon layer may have a higher sheet resistance, such that the polysilicon gate electrode may have a greater contact resistance when the integration degree of a semiconductor device is higher. As a result, the polysilicon gate electrode may not be suitable for a higher integrated semiconductor device requiring a lower electrical resistance.

To reduce the electrical resistance of the polysilicon gate electrode, a refractory metal silicide layer having an improved heat resistance may be formed on the polysilicon layer to thereby form a multi-layered structure including the polysilicon layer and the metal silicide layer on the polysilicon layer (e.g., a polycide gate electrode). However, the decreased electrical resistance of the polycide gate electrode may still not suffice the lower resistance requirements of a ultra-large scale integrated (ULSI) circuit.

To reduce the electrical resistance of the polycide gate electrode, a poly-metal gate electrode may be used in place of the polycide gate electrode. The poly-metal gate electrode may have a higher heat stability and a lower electrical resistance than the polycide gate electrode. The poly-metal gate electrode may have a multi-layered structure, wherein a conductive metal layer having a higher heat resistance may be formed on a polysilicon layer doped with impurities, such that the poly-metal gate electrode has an electrical resistance lower than the polysilicon gate electrode or the polycide gate electrode. Thus, although a line width of a circuit may be reduced to a smaller size (e.g., ULSI circuit), a semiconductor device including the poly-metal gate electrode may have a relatively stable operation speed, because of the reduced electrical resistance of the gate electrode due to the conductive metal layer of the poly-metal gate electrode. For example, a tungsten (W) layer may be used as the conductive metal layer of the poly-metal gate electrode (e.g., tungsten/polysilicon gate electrode), because the tungsten layer may have an electrical resistance of about 10 micro-ohm/cm or less.

FIG. 1 is a cross-sectional view illustrating a conventional semiconductor device including a tungsten/polysilicon gate electrode. Referring to FIG. 1, the conventional semiconductor device 90 may include a gate insulating layer 12 on a semiconductor substrate 10 (e.g., a silicon wafer) and a tungsten/polysilicon gate electrode structure 80 on the gate insulating layer 12. The tungsten/polysilicon gate electrode structure 80 may include a polysilicon layer 14 on the gate insulating layer 12, a tungsten silicide (WSiₓ) layer 16 on the polysilicon layer 14, a tungsten nitride (WN) layer 18 on the tungsten silicide layer 16, and a tungsten layer 20 on the tungsten nitride layer 18.

The gate insulating layer 12 may electrically insulate the gate electrode structure 80 from the substrate 10. The gate insulating layer 12 may include silicon oxide. The polysilicon layer 14 may be doped with impurities (e.g., boron (B), phosphorus (P), arsenic (As)) and may have an electrically-sufficient conductivity. The tungsten nitride layer 18 may reduce or prevent the diffusion of impurities from the polysilicon layer 14 to the tungsten layer 20. In addition, the tungsten nitride layer 18 may improve the adhesion between the polysilicon layer 14 and the tungsten layer 20. The tungsten silicide layer 16 may reduce or prevent a chemical reaction (e.g., interfacial reaction) between nitrogen (N) and silicon (Si) at an interface between the tungsten nitride (WN) layer 18 and the polysilicon layer 14, thus reducing or preventing the formation of an interfacial insulating layer (e.g., a silicon nitride layer) between the tungsten nitride layer 18 and the polysilicon layer 14. Furthermore, the tungsten silicide layer 16 may prevent an interfacial reaction between the tungsten nitride layer 18 and the polysilicon layer 14 due to an oxidizer in a selective re-oxidation process. Accordingly, the tungsten nitride layer 18 may reduce a contact resistance at an interface between the polysilicon layer 14 and the tungsten nitride layer 18, thus improving an ohmic characteristic of the tungsten/polysilicon gate electrode structure 80.

The gate insulating layer 12, the polysilicon layer 14, the tungsten silicide layer 16, the tungsten nitride layer 18, and the tungsten layer 20 may be sequentially formed on the substrate 10 and patterned by a photolithography process using a mask layer (not shown) to achieve the conventional tungsten/polysilicon gate electrode structure 80 shown in FIG. 1. However, the above-mentioned method of forming the conventional tungsten/polysilicon gate electrode structure 80 may have various disadvantages.

During a process of depositing tungsten (W) onto a surface of the tungsten nitride layer 18, the tungsten nitride layer 18 may react with the tungsten suicide layer 16 to form a tungsten silicon nitride (WSiₓN_{y}) layer having a larger electrical resistance at the interface between the tungsten nitride layer 18 and the tungsten silicide layer 16. The tungsten silicide layer 16 may be formed to reduce or prevent the generation of an interface insulating layer by a nitrogen component of the tungsten nitride layer 18. However, during the process of forming the tungsten layer 20, the nitrogen component of the tungsten nitride layer 18 may react with a silicon component of the tungsten silicide layer 16 to form an interfacial insulating layer having a larger electrical resistance between the tungsten silicide layer 16 and the tungsten nitride layer 18. Furthermore, the tungsten nitride (WN) of the tungsten nitride layer 18 may dissociate into tungsten (W) and nitrogen (N), and the tungsten nitride layer 18 may be reduced in thickness because of the generation of the interfacial insulating layer. As a result, the tungsten nitride layer 18 may not sufficiently reduce or prevent the diffusion of impurities from the polysilicon layer 14 to the tungsten layer 20.

Experimental results may show that the reactivity between a tungsten nitride layer and a tungsten silicide layer may depend on the mole ratio of tungsten (W) and silicon (Si) in the tungsten silicide layer. Table 1 shows tungsten (W) reactivity with respect to the mole ratio of tungsten (W) and silicon (Si) in the tungsten silicide layer. The experimental results in Table 1 were obtained by an experiment performed at a temperature of about 800° C. and a pressure of about 1 atmospheric pressure.

TABLE 1

| | | | | | | |
|---|---|---|---|---|---|---|
| Reactant | W₂Si + W | WSi + W | WSi₂ + W | WSi₃ + W | WSi₄ + W | WSi₅ + W |
| (mole) | | | | | | |
| Product | 1.33W | 0.33W | — | — | — | — |
| (mole) | 0.33W₅Si₃ | 0.33W₅Si₃ | 0.57WSi₂ | 1.28WSi₂ | 2.00WSi₂ | 2.00WSi₂ |
| | | | 0.28W₅Si₃ | 0.14W₅Si₃ | | 1.00Si |
| Reaction Ratio of | 0% | 67% | 100% | 100% | 100% | 100% |
| Tungsten | | | | | | |

Table 1 shows that when a tungsten mole fraction is greater than a silicon mole fraction in a tungsten suicide layer (e.g., tungsten-rich tungsten silicide layer), tungsten (W) was not reacted with tungsten silicide (WSi). However, when the tungsten mole fraction is equal to the silicon mole fraction in a tungsten silicide layer, about 0.67 mole of tungsten (W) was reacted with tungsten silicide (WSi), and about 0.33 mole of tungsten (W) remained non-reacted in the tungsten silicide layer, so that about 67 percent of tungsten (W) was reacted with tungsten silicide (WSi). When a silicon mole fraction is greater than a tungsten mole fraction in a tungsten silicide layer (silicon-rich tungsten silicide layer), all of tungsten (W) was reacted with tungsten silicide (WSi).

In view of the experimental results in Table 1, a reaction between a tungsten silicide layer and a tungsten nitride layer may not occur where the tungsten silicide layer includes tungsten-rich tungsten silicide. Because the reaction may not occur, the tungsten nitride molecules of the tungsten nitride layer may not dissociate into tungsten (W) and nitrogen (N). Consequently, the thickness of the tungsten nitride layer may be maintained so as to preserve its barrier characteristics. In contrast, a reaction between a tungsten silicide layer and a tungsten nitride layer may occur where the tungsten silicide layer includes silicon-rich tungsten silicide. Because the reaction may occur, the tungsten nitride molecules of the tungsten nitride layer may dissociate into tungsten (W) and nitrogen (N) during a deposition process or a thermal treatment process. Consequently, the thickness of the tungsten nitride layer may be reduced so as to deteriorate its barrier characteristics.

The mole ratio of metal to silicon in the tungsten silicide layer 16 may be about 1:5 or more for the tungsten silicide layer 16 to function as an ohmic layer between the polysilicon layer 14 and the tungsten layer 20. Thus, the tungsten silicide layer 16 includes silicon-rich tungsten silicide. Consequently, the tungsten nitride layer 18 may dissociate into tungsten (W) and nitrogen (N) during a deposition process or a thermal treatment process. Accordingly, the tungsten nitride layer 18 may not sufficiently reduce or prevent the diffusion of impurities from the polysilicon layer 14 into the tungsten layer 20.

Furthermore, an agglomeration may be generated on the surface of the tungsten silicide layer 16 during a thermal treatment process, which may reduce its ohmic characteristic. FIG. 2 is a scanning electron microscope (SEM) image showing the agglomeration generated on a conventional tungsten silicide layer as a result of a thermal treatment process at a temperature of about 815° C. As shown in FIG. 2, the tungsten silicide layer may be partially agglomerated to a height of about 95 Å after the thermal treatment process, thus increasing the thickness of the tungsten silicide layer 16. Consequently, the sheet resistance of the tungsten silicide layer 16 may increase as a result of the increase in thickness. However, the increase in sheet resistance of the tungsten suicide layer 16 may deteriorate the ohmic characteristic of the tungsten/polysilicon gate electrode structure 90, thereby decreasing reliability.

To reduce or prevent an increase in the thickness of the metal silicide layer, a titanium silicide (TiSiₓ) layer may be used instead of the tungsten suicide layer (WSi) 16. However, forming the titanium suicide layer to a desired thickness may be difficult. Because the titanium silicide layer may be formed by a sputtering process or a chemical vapor deposition (CVD) process at a temperature higher than about 600° C., the reactivity of titanium (Ti) with silicon (Si) may increase. As a result, controlling the final thickness of the titanium silicide layer may be difficult. Additionally, the titanium silicide layer may have surface defects (e.g., agglomerations, voids). Furthermore, because the titanium silicide layer may need to include a silicon-rich titanium silicide to improve its ohmic characteristic, a tungsten nitride layer 18 on the titanium silicide layer may be reduced in thickness due to dissociation of the tungsten nitride (WN) during a thermal treatment process. Thus, a titanium silicide layer may not improve the decreased barrier characteristic of the tungsten nitride layer 18.

### SUMMARY OF EXAMPLE EMBODIMENTS

Example embodiments provide a semiconductor device having a poly-metal gate electrode capable of reducing or preventing the dissociation of a barrier layer and/or the generation of an agglomeration at a surface of an interface reaction preventing layer. Example embodiments also provide a method of manufacturing the semiconductor device having the above poly-metal gate electrode.

A semiconductor device according to example embodiments may include a gate insulating layer, a polysilicon layer, an interface reaction preventing layer, a barrier layer, and a conductive metal layer. The gate insulating layer may be formed on a semiconductor substrate. The polysilicon layer may be formed on the gate insulating layer and may be doped with impurities. The interface reaction preventing layer may be formed on the polysilicon layer and may include a metal-rich metal suicide having a metal mole fraction greater than a silicon mole fraction. The barrier layer may be formed on the interface reaction preventing layer and may reduce or prevent the diffusion of impurities doped in the polysilicon layer. In addition, the interface reaction preventing layer may reduce or prevent a chemical interfacial reaction with the barrier layer. The conductive metal layer may be formed on the barrier layer and may include a refractory metal.

The mole ratio of metal to silicon in the metal silicide layer may be in the range of about 1:1 to about 4:1. For example, the metal silicide layer may include one of tungsten silicide, titanium silicide, and tantalum silicide. The barrier layer may include a nitride layer including a refractory metal. For example, the nitride may be one of a tungsten nitride, titanium nitride, and tantalum nitride. The conductive metal layer may include one of a tungsten layer, titanium layer, and tantalum layer. The semiconductor device may further include source/drain regions and a channel region. The source/drain regions may be doped with impurities formed at the surface of the substrate. The channel region may be formed at a surface of the substrate between the source/drain regions.

A method of manufacturing a semiconductor device according to example embodiments may include forming a first layer on a semiconductor substrate and forming a second layer doped with impurities on the first layer. A third layer may be formed on the second layer and may include a metal-rich metal silicide having a metal mole fraction greater than a silicon mole fraction. A fourth layer may be formed on the third layer, wherein the fourth layer may reduce or prevent the diffusion of impurities doped in the second layer. The third layer may reduce or prevent a chemical interfacial reaction with the fourth layer. A fifth layer may be formed on the fourth layer and may include a refractory metal. The fifth layer, the fourth layer, the third layer, the second layer, and the first layer may be sequentially patterned to form a gate electrode including a gate insulating layer, a polysilicon layer, an interface reaction preventing layer, a barrier layer, and a conductive metal layer on the semiconductor substrate.

The first layer may be formed to a thickness of about 10 Å to about 100 Å by a thermal oxidation process. The second layer may be formed to a thickness of about 500 Å to about 2000 Å by chemical vapor deposition (CVD) process using a source gas including silane (SiH₄) gas and an impurities gas. The third layer may be formed on the second layer to a thickness of about 10 Å to about 50 Å. The third layer may be a metal-rich metal silicide, wherein a mole ratio of metal to silicon in the metal-rich metal silicide may be in the range of about 1:1 to about 4:1. The metal silicide may include tungsten, titanium, tantalum, and other suitable metals.

To form the third layer, a dummy metal layer may be formed on the second layer, and a thermal treatment may be performed on the dummy metal layer under a nitrogen atmosphere. The dummy metal layer may be formed on the second layer by one of a sputtering process, a CVD process, and an atomic layer deposition (ALD) process. The thermal treatment for the dummy metal layer may be performed at a temperature of about 400° C. to about 600° C. using ammonia (NH₃) gas or a mixture of ammonia (NH₃) gas and hydrogen (H₂) gas. Additionally, a lower portion of the dummy metal layer contacting the second layer may be transformed into a metal silicide by the thermal treatment to thereby form the third layer, and an upper portion of the dummy metal layer may be transformed into a metal nitride by the thermal treatment to thereby form the fourth layer, so that the third layer and the fourth layer may be simultaneously formed on the second layer.

The third layer may also be formed by providing titanium chloride (TiCl₄) gas and hydrogen (H₂) gas to a processing chamber having a pressure of about 0.5 Torr to about 10 Torr and a temperature of about 400° C. to about 600° C. The titanium chloride (TiCl₄) gas and hydrogen (H₂) gas may be deposited onto the second layer by a CVD process to thereby form a titanium silicide layer on the second layer.

Alternatively, a metal silicide layer may be formed on the second layer by an ALD process using a metal precursor and hydrogen (H₂) gas as a reaction gas at a temperature of about 400° C. to about 600° C. to form the third layer. Alternatively, a dummy metal layer may be formed on the second layer by a CVD process using a metal precursor and a hydrogen (H₂) gas at a temperature of about 400° C. to about 600° C., wherein the dummy metal layer may be transformed into a metal silicide layer by a hydrogen (H₂) plasma treatment or an ammonia (NH₃) plasma treatment to thereby form the third layer. Alternatively, a metal silicide layer may be formed on the second layer by an ALD process using a metal precursor and a silane (SiH₄) gas as a reaction gas at a temperature of about 400° C. to about 600° C. to form the third layer.

To form the fourth layer, an argon (Ar) gas and a nitrogen gas may be provided to a processing chamber containing a target metal and a substrate having the third layer. Plasma may be generated in the processing chamber, and a metal nitride layer may be formed on the third layer by a chemical reaction between nitrogen atoms of the nitrogen gas activated by the plasma and metal atoms sputtered from the target metal by the plasma. The target metal may include one of tungsten, titanium, and tantalum. To generate the plasma, electrical power of about 0.3 kW to about 1.2 kW may be supplied to the processing chamber. For example, the nitrogen gas may be removed from the processing chamber and the electrical power supplied to the processing chamber may be increased to about 0.5 kW to about 1.6 kW to form the fifth layer on the fourth layer.

A metal nitride layer may be formed on the third layer by a CVD process or an ALD process to form the fourth layer. The metal nitride layer may include one of a tungsten nitride layer, a titanium nitride layer, and a tantalum nitride layer. The fourth layer may be formed to a thickness of about 10 Å to about 100 Å.

To form the fifth layer, a refractory metal may be deposited on the fourth layer by one of a sputtering process, a CVD process, a PVD process, and an ALD process. For example, the refractory metal may include one of tungsten, titanium, tantalum, and alloys thereof.

Source/drain regions may be formed on the surface of the substrate adjacent to the gate electrode by injecting impurities onto the surface of the substrate by an ion implantation process using the gate electrode as an ion implantation mask.

According to example embodiments, a metal-rich metal silicide may be used as the interface reaction preventing layer, so that a chemical reaction between the interface reaction preventing layer and the barrier layer may be reduced or prevented during a thermal treatment process at a higher temperature. Therefore, the interface reaction preventing layer may improve the barrier characteristic of the barrier layer. Further, the interface reaction preventing layer may be formed relatively uniformly by a lower temperature process, so that surface agglomerations may be sufficiently reduced or prevented.

### BRIEF DESCRIPTION OF THE DRAWINGS

FIG. 1 is a cross-sectional view illustrating a conventional semiconductor device including a tungsten/polysilicon gate electrode.

FIG. 2 is a scanning electron microscope (SEM) picture showing an agglomeration generated on the tungsten silicide layer of a conventional semiconductor device during a thermal treatment process.

FIG. 3 is a cross-sectional view illustrating a semiconductor device including a poly-metal gate electrode according to example embodiments.

FIGS. 4A to 4F are cross-sectional views illustrating a process for manufacturing the semiconductor device of FIG. 3 according to example embodiments.

FIGS. 5A to 5D are scanning electron microscope (SEM) pictures measuring the adhesiveness of a titanium-rich titanium silicide (TiSiₓ) layer formed in a lower temperature process according to example embodiments.

FIG. 6 is a transmission electron microscope (TEM) picture measuring the adhesiveness of a titanium-rich titanium silicide (TiSiₓ) layer conformally formed on a gate insulating layer according to example embodiments.

FIGS. 7A to 7D are scanning electron microscope (SEM) pictures measuring the adhesiveness of a conventional titanium-rich titanium silicide (TiSiₓ) layer formed in a higher temperature process.

FIG. 8 is a graph estimating a voltage-current characteristic of a poly-metal gate electrode including a titanium-rich titanium silicide (TiSiₓ) layer according to example embodiments.

FIG. 9 is a graph showing an auger electron spectroscopy (AES) analysis result of a titanium-rich titanium silicide (TiSiₓ) layer formed in a lower temperature process according to example embodiments.

FIG. 10 is a graph showing an auger electron spectroscopy (AES) analysis result of a conventional titanium-rich titanium silicide (TiSiₓ) layer formed in a higher temperature process.

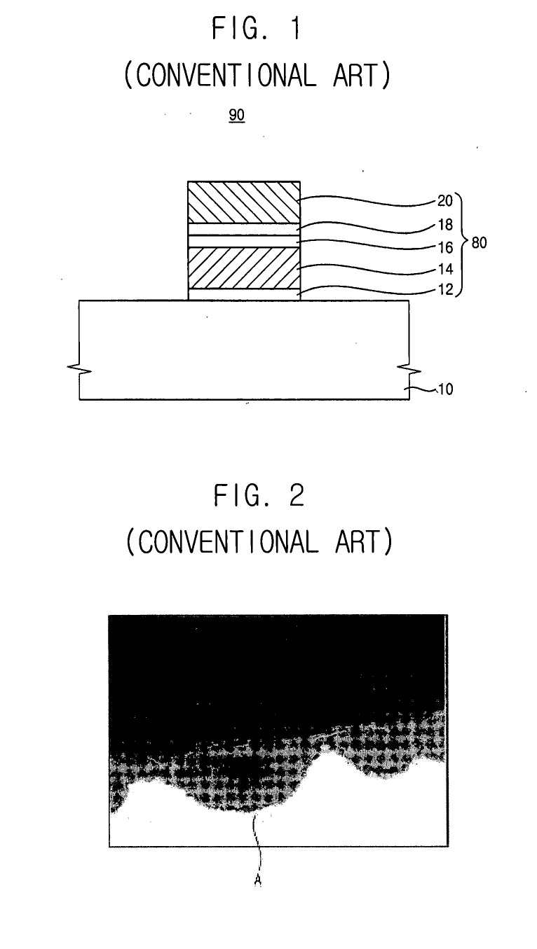

### DETAILED DESCRIPTION OF EXAMPLE EMBODIMENTS

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

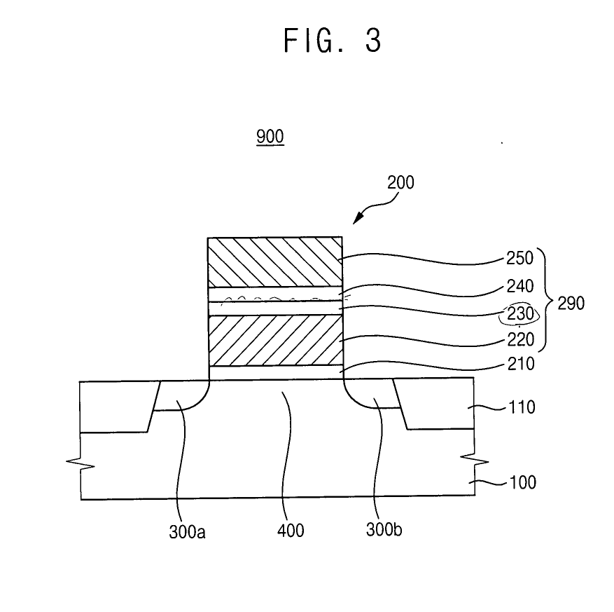

FIG. 3 is a cross-sectional view illustrating a semiconductor device including a poly-metal gate electrode according to example embodiments. Referring to FIG. 3, the semiconductor device 900 may include a gate electrode 200, source/drain electrodes 300a and 300b, and a channel region 400. The gate electrode 200 may have a poly-metal structure formed on a substrate 100. The source/drain electrodes 300a and 300b may be formed on the surface of the substrate 100 adjacent to the gate electrode 200. The channel region 400 may be formed under the gate electrode 200, and the source/drain electrodes 300a and 300b may be electrically connected to each other by the channel region 400.

The substrate 100 may include a silicon substrate, a silicon-on-insulator (SOI) substrate, a germanium substrate, a germanium-on-insulator (GOI) substrate, a silicon-germanium substrate, and an epitaxial layer obtained by a selective epitaxial growth (SEG) process. For example, the substrate 100 may include a silicon wafer. The substrate 100 may include p-type well (not shown) or n-type well (not shown).

The substrate 100 may include an active region where a variety of conductive structures may be formed and a field region surrounding the active region. An insulating layer may be formed on the field region so that the conductive structures formed on the adjacent active regions may be electrically isolated from each other. For that reason, the insulating layer on the field region of the substrate 100 may be referred to as a device isolation layer 110. For example, the device isolation layer 110 may be a field oxide layer or a trench isolation layer. A trench isolation layer may be used as the device isolation layer 110, because the trench isolation layer may permit a higher degree of integration than a field oxide layer.

The source/drain regions 300a and 300b doped with impurities may be formed at a surface of the substrate 100. The source/drain regions 300a and 300b may be formed at the surface of the substrate 100 adjacent to the gate electrode 200 by an ion implantation process. The channel region 400 may be formed under the gate electrode 200 between the source/drain regions 300a and 300b.

The gate electrode 200 may be formed on the channel region 400 of the substrate 100. The gate electrode 200 may include a poly-metal electrode structure 290 and a gate insulating layer 210. The gate insulating layer 210 may be formed between the poly-metal electrode structure 290 and the channel region 400. The gate insulating layer 210 may electrically insulate the poly-metal electrode structure 290 from the channel region 400, thus reducing or preventing a current leakage between the electrode structure 290 and the substrate 100. The gate insulating layer 210 may include a silicon oxide layer formed on a surface of the substrate 100 by a thermal oxidation process to a thickness of about 10 Å to about 100 Å. The gate insulating layer 210 may include a metal oxide layer or a metal silicide layer provided that the metal oxide layer or the metal silicide layer has a sufficiently small equivalent oxide thickness (EOT) so as to sufficiently reduce or prevent current leakage through the gate insulating layer 210.

The poly-metal electrode structure 290 may include a multi-layer structure having a polysilicon layer 220, an interface reaction preventing layer 230, a barrier layer 240, and a conductive metal layer 250 sequentially stacked on the gate insulating layer 210. The polysilicon layer 220 may have a smaller resistivity (e.g., electrical resistance) and a higher oxidation resistance. The polysilicon layer 220 may have a higher stability so as to have sufficient mechanical stability with respect to an externally applied force. Furthermore, the polysilicon layer 220 may be doped with impurities so as to have sufficient electrical conductivity. The impurities may include a group III or group V element depending on the electrical polarity of the semiconductor device. The polysilicon layer 220 may have a thickness of about 500 Å to about 2000 Å.

The conductive metal layer 250 may have a lower resistivity and may be provided on the polysilicon layer 220. The conductive metal layer 250 may include a refractory metal that is sufficiently resistive to a thermal treatment process. The refractory metal of the conductive metal layer 250 may include tungsten (W), titanium (Ti), tantalum (Ta), and alloys thereof. For example, the conductive metal layer 250 may include tungsten, which may have a lower resistivity than the other refractory metals, and may have a thickness of about 500 Å to about 1000 Å.

The barrier layer 240 may reduce or prevent the diffusion of impurities from the polysilicon layer 220 into the conductive metal layer 250 during a process of depositing a refractory metal onto the polysilicon layer 220. Thus, the barrier layer 240 may reduce or prevent the silicidation of the refractory metal during the deposition process and may improve the adhesiveness of the conductive metal layer 250 and the polysilicon layer 220. The barrier layer 240 may include a nitride including a refractory metal (e.g., a tungsten nitride (WN) layer, a titanium nitride (TiN) layer, and a tantalum nitride (TaN) layer). The barrier layer 240 may include a metal nitride having the same metal component as the conductive metal layer 250 or as that of the metal silicide of the interface reaction preventing layer 230. For example, the barrier layer 240 may include a tungsten nitride (WN) layer, and the conductive metal layer 250 may include a tungsten (W) layer, or the barrier layer 240 may include a titanium nitride (TiN) layer, and the interface reaction preventing layer 230 may include a titanium silicide layer. The barrier layer 240 may have a thickness of about 10 Å to about 100 Å.

The interface reaction preventing layer 230 may be interposed between the barrier layer 240 and the polysilicon layer 220. The interface reaction preventing layer 230 may reduce or prevent the generation of an interface insulating layer having a higher resistance (e.g., a silicon nitride layer) on a surface of the polysilicon layer 220 and may reduce or prevent an interfacial reaction by an oxidizer during a re-oxidation process. The interface reaction preventing layer 230 may include a refractory metal silicide (e.g., titanium silicide (TiSiₓ), tantalum silicide (TaSiₓ)). Accordingly, the electrical resistance at an interface between the polysilicon layer 220 and the conductive metal layer 250 may be sufficiently reduced or prevented to thereby improve the ohmic characteristic of the poly-metal electrode structure 290. The interface reaction preventing layer 230 may have a thickness of about 10 Å to about 50 Å.

The interface reaction preventing layer 230 may include a metal silicide having a mole ratio of metal to silicon (metal:Si) about equal to or greater than 1:1. Consequently, an interfacial reaction between the interface reaction prevention layer 230 and the barrier layer 240 may be reduced or prevented during a thermal treatment performed at a relatively high temperature. The interface reaction preventing layer 230 may include a metal silicide having a mole ratio of metal to silicon (metal:Si) about equal to or greater than 2:1. However, when the mole ratio of metal to silicon (metal:Si) is more than about 4:1 in the interface reaction preventing layer 230, formation of the interface reaction preventing layer 230 may take longer, thus reducing process efficiency. Accordingly, it may be beneficial for the interface reaction preventing layer 230 to have a mole ratio of metal to silicon (metal:Si) in the range of about 2:1 to about 4:1. The interface reaction preventing layer 230 may reduce or prevent the thinning of the barrier layer 240 during a thermal treatment process, thus preserving its barrier characteristic.

The interface reaction preventing layer 230 may include titanium silicide, wherein the mole ratio of titanium (Ti) to silicon (Si) may be about equal to or greater than 1:1 (e.g., titanium-rich titanium silicide), so that the metallic properties may be more dominant in the interface reaction preventing layer 230. Consequently, an interfacial reaction at the interface of the interface reaction preventing layer 230 and the barrier layer 240 may be reduced or prevented during a higher temperature thermal treatment process to thereby reduce or prevent dissociation of the barrier layer 240.

Titanium-rich titanium silicide may be deposited at a lower temperature of about 400° C. to about 600° C. The deposition process may be easier to control because of the slower reaction rate between titanium and silicon. Accordingly, the titanium-rich titanium silicide layer may be formed relatively uniformly on the surface of the polysilicon layer 220 while reducing or preventing the generation of agglomerations and/or voids. As described in the following experimental results, the relative uniformity of the titanium-rich titanium silicide layer may be maintained during a thermal treatment performed at a higher temperature to thereby reduce or prevent the agglomeration of the titanium-rich titanium silicide layer and the increased sheet-resistance caused by the agglomeration. Therefore, the ohmic characteristic of the poly-metal electrode structure 290 may be improved.

The semiconductor device 900 may further include a spacer (not shown) at a side portion of the gate electrode 200. For example, the source/drain electrodes 300a and 300b may have a light junction area where the impurities may be implanted by an ion implantation process using the gate electrode 200 as an ion implantation mask and a heavy junction area where the impurities may be implanted by an ion implantation process using the spacer as an ion implantation mask.

As mentioned above, the semiconductor device 900 may include the poly-metal gate electrode 200 having the interface reaction preventing layer 230 with the metal-rich metal silicide. Accordingly, a chemical reaction at the interface between the interface reaction preventing layer 230 and the barrier layer 240 may be reduced or prevented during a higher temperature thermal treatment process, thus preserving the barrier characteristic of the barrier layer 240. In addition, the interface reaction preventing layer 230 may have a relatively uniform thickness because of a lower temperature process, thus reducing or preventing agglomerations at the surface of the interface reaction preventing layer 230.

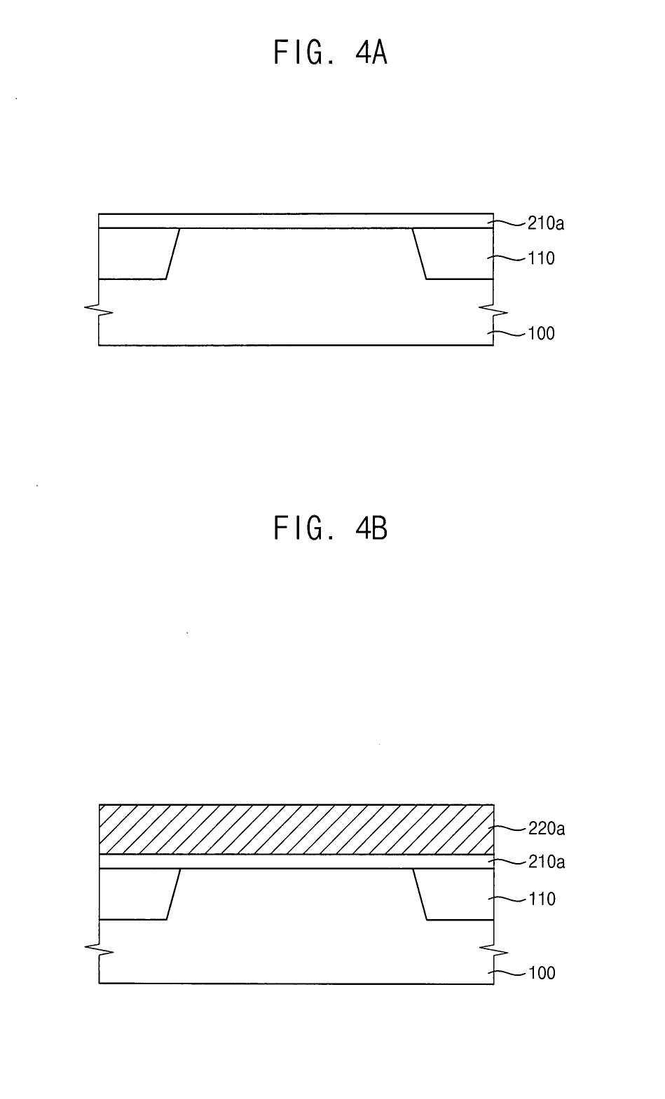

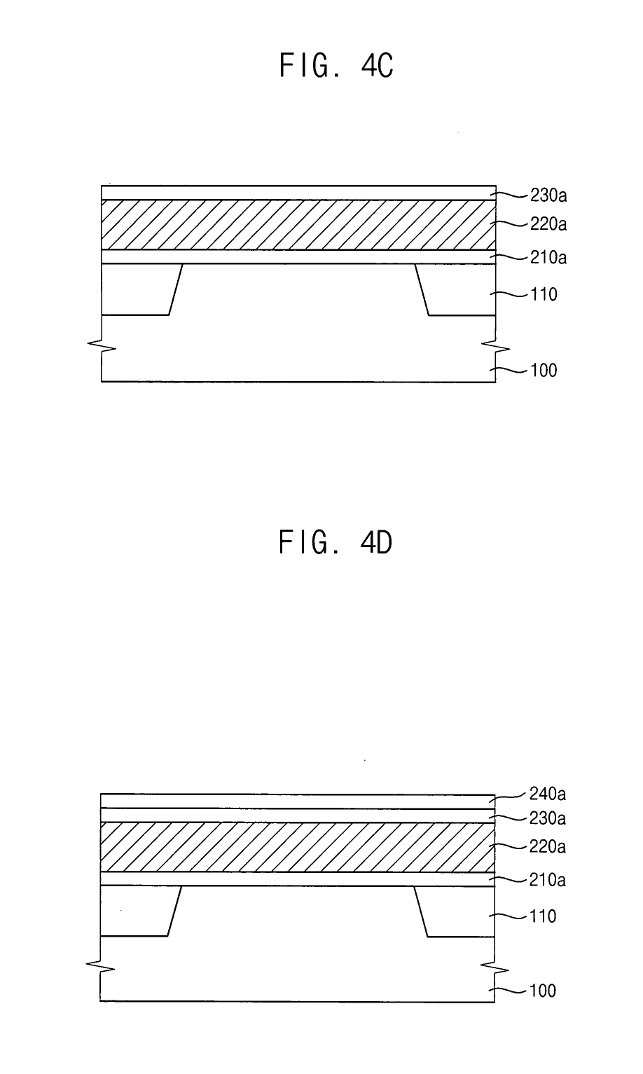

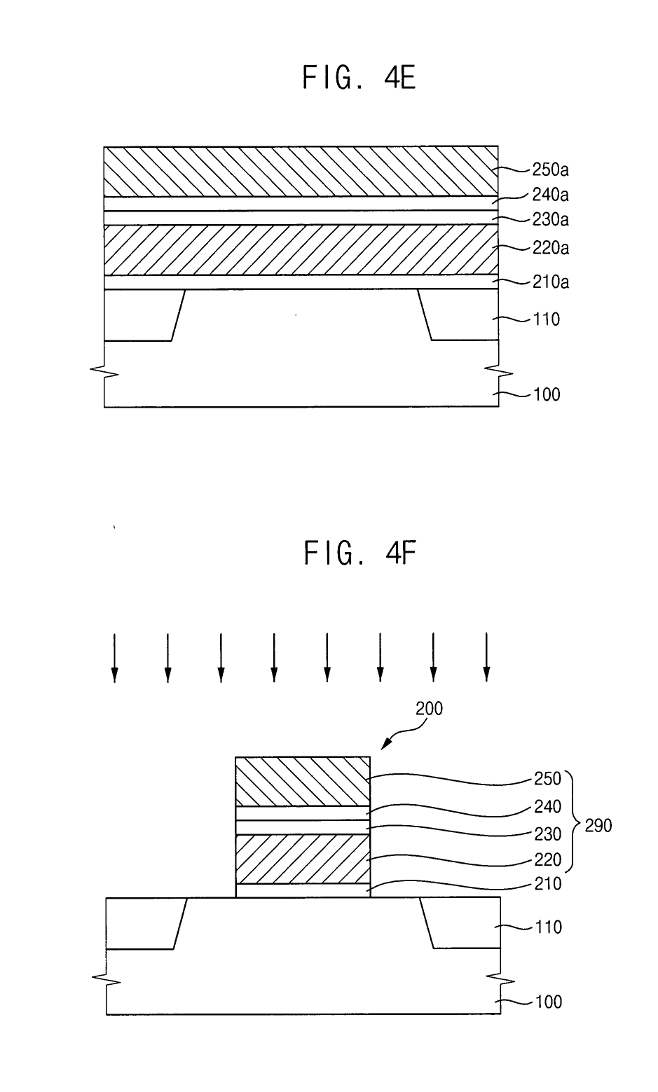

FIGS. 4A to 4F are cross-sectional views illustrating processing steps for manufacturing the semiconductor device shown in FIG. 3 according to example embodiments. Referring to FIG. 4A, a trench isolation layer may be formed on a semiconductor substrate 100 as a device isolation layer 110, thereby defining an active region and a field region on the substrate 100. A pad oxide layer and a pad nitride layer may be formed on the substrate 100 and may be patterned into a pad oxide layer pattern and a pad nitride layer pattern through which the substrate 100 is partially exposed. A trench may be formed on the semiconductor substrate 100 by an etching process using the pad oxide layer pattern and the pad nitride layer pattern as etch masks. An oxide layer having an increased fill-up characteristic may be formed to a sufficient thickness on the resultant structure including the trench so as to fill the trench using a plasma-enhanced chemical vapor deposition (PECVD) process. As a result, the trench may be filled with the oxide layer. The oxide layer, the pad nitride layer pattern, and the pad oxide layer pattern may be removed from the substrate 100 until a top surface of the substrate 100 is exposed using a planarization process (e.g., a chemical mechanical polishing (CMP) process), so that the oxide layer remains in the trench to thereby form the trench isolation layer on the substrate 100 as the device isolation layer 110.

A first layer 210a may be formed on the substrate 100 including the device isolation layer 110. The first layer 210a may be formed into a gate insulating layer 210 of the gate electrode 200 by a subsequent process. The first layer 210a may include a silicon oxide layer on the substrate 100. A thermal treatment may be performed on the substrate 100 including the device isolation layer 110 at a temperature of about 850° C. for about 4 hours under an atmosphere having an oxygen gas or vapor to thereby form the silicon oxide layer on the substrate 100 to a thickness of about 10 Å to about 100 Å. The first layer 210a may include a metal oxide layer and a metal silicate layer in accordance with characteristics of the semiconductor device 900. The metal oxide layer and the metal silicate layer may be formed on the substrate 100 by a CVD process, a sputtering process, or ALD process.

Referring to FIG. 4B, a second layer 220a may be formed on the first layer 210a. The second layer 220a may be formed into a polysilicon layer 220 of the poly-metal electrode structure 290 by a subsequent process. The second layer 220a may be formed by thermal dissociation of a source gas (e.g., silane (SiH₄) gas) during a CVD process. When a mixture of silane (SiH₄) gas and phosphine (PH₃) gas is provided into a processing chamber having a temperature of about 500° C. to about 650° C. and a pressure of about 25 Pa to about 150 Pa and the substrate 100 including the first layer 210a is provided in the processing chamber, the silane (SiH₄) gas may be deposited onto a surface of the first layer 210a to thereby form a polysilicon layer on the first layer 210a, and phosphorus (P) may be doped into the polysilicon layer as an impurity. Thus, the second layer 220a including the polysilicon layer doped with phosphorus (P) may be formed on the surface of the first layer 210a. While example embodiments disclose phosphorus (P) as the impurity doped into the polysilicon layer, various elements from Group III or Group V of the periodic table (e.g., boron (B), arsenic (As)) may be used as impurities in the polysilicon layer depending on the usage and characteristics of the semiconductor device. The second layer 220a may be formed to a thickness of about 500 Å to about 2000 Å on the first layer 210a.

Referring to FIG. 4C, a third layer 230a may be formed on the second layer 220a. The third layer 230a may be formed into an interface reaction preventing layer 230 of the poly-metal electrode structure 290 by a subsequent process. The interface reaction preventing layer 230 may be formed between the barrier layer 240 and the polysilicon layer 220 and may reduce or prevent the generation of an interface insulating layer having a higher resistance based on silicon nitride of the polysilicon layer 220 and the interfacial reaction caused by an oxidizer during a re-oxidation process. Accordingly, the third layer 230a may include metal silicide layer having a refractory metal. For example, the metal silicide layer may include tungsten silicide (WSiₓ), titanium silicide (TiSiₓ), and tantalum silicide (TaSiₓ).

Hereinafter, a formation process of the third layer 230a will be described. A titanium silicide layer may be formed on the second layer 220a as the third layer 230a. However, a tantalum silicide layer may be formed on the second layer 220a by the same lower temperature process that may be used to form the titanium silicide layer although some processing conditions for the tantalum silicide layer may differ from those for the titanium silicide layer. For that reason, the tantalum silicide layer may be suitable as the third layer 230a.

The third layer 230a including titanium silicide may be formed by a thermal treatment process. Titanium may be deposited onto a surface of the second layer 220a by a CVD process, a sputtering process, or an ALD process. The third layer 230a may be formed to a thickness of about 10 Å to about 50 Å. A thermal treatment may be performed on the titanium layer at a relatively low temperature of about 400° C. to about 600° C. in a nitrogen atmosphere. The titanium layer on the second layer 220a may be transformed into a titanium silicide (TiSiₓ) layer due to heat applied during the thermal treatment. Accordingly, the titanium silicide layer may be formed on the second layer 220a as the third layer 230a. The titanium silicide layer may include titanium-rich titanium silicide, wherein a mole ratio of titanium (Ti) to silicon (Si) may be equal to or greater than 1:1. For example, the titanium silicide layer may include titanium-rich titanium silicide, wherein a mole ratio of titanium (Ti) to silicon (Si) may be equal to or greater than 2:1. However, when the mole ratio of titanium (Ti) to silicon (Si) is more than 4:1 in the titanium-rich titanium silicide, it may take longer to form the titanium silicide layer, thus reducing process efficiency. Accordingly, the titanium silicide layer may have a mole ratio of titanium (Ti) to silicon (Si) in the range of about 2:1 to about 4:1.

The third layer 230a including titanium silicide may be formed on the second layer 220a by a deposition process (e.g., a CVD process, an ALD process) rather than a thermal treatment. The substrate 100 including the second layer 220a may be provided in a processing chamber having a temperature in the range of about 400° C. to about 600° C. and a pressure in the range of about 0.5 Torr to about 10 Torr. Titanium chloride (TiCl₄) gas and hydrogen (H₂) gas may be provided into the processing chamber. Titanium chloride (TiCl₄) may chemically react with the polysilicon of the second layer 220a to thereby form the titanium silicide layer on the second layer 220a. The titanium chloride (TiCl₄) gas and the hydrogen (H₂) gas may be provided into the processing chamber in an amount such that a mole ratio of titanium (Ti) to silicon (Si) may be in the range of about 1:1 to about 4:1 in the resulting titanium silicide layer.

Where an ALD process is used for forming the third layer 230a including titanium silicide, a titanium precursor and monosilane (SiH₄) gas may be provided into a processing chamber as a reaction gas. Hydrogen (H₂) gas may be provided into the processing chamber in place of the monosilane (SiH₄) gas as the reaction gas. The processing conditions of the ALD process may be controlled in such a manner that a mole ratio of titanium (Ti) to silicon (Si) may be in the range of about 1:1 to about 4:1 in the resulting titanium silicide layer.

The third layer 230a including titanium silicide may be formed by a cyclic chemical vapor deposition (CVD) process using a titanium precursor and hydrogen (H₂) gas. The substrate 100 including the second layer 220a may be provided into a processing chamber having a temperature in the range of about 400° C. to about 600° C. along with a titanium (Ti) precursor and hydrogen (H₂) gas. A dummy titanium layer may be formed on the second layer 220a by the CVD process. The dummy titanium layer may be transformed into a titanium silicide layer by a hydrogen (H₂) plasma treatment process or an ammonium (NH₃) plasma treatment process. Accordingly, the titanium silicide layer may be formed on the second layer 220a as the third layer 230a by the cyclic CVD process, wherein a unit cycle may include a CVD process and a plasma treatment.

The formation process of the titanium silicide layer may be performed at a lower temperature than a conventional process, thus rendering the formation process easier to control. Consequently, the third layer 230a may be formed on the second layer 220a at a relatively uniform thickness so as to sufficiently reduce or prevent processing defects (e.g., local agglomeration, void). The third layer 230a may include titanium-rich titanium silicide, wherein a mole ratio of titanium (Ti) with respect to silicon (Si) may be larger than 1:1 because of the lower temperature process. Accordingly, a chemical reaction on an interface between the third layer 230a and a fourth layer 240a may be reduced or prevented during a higher temperature thermal treatment process. Thus, the dissociation of the fourth layer 240a may be reduced or prevented during a thermal treatment process to thereby reduce or prevent thinning of the fourth layer 240a during the thermal treatment process.

Referring to FIG. 4D, the fourth layer 240a may be formed on the third layer 230a. The fourth layer 240a may be formed into a barrier layer 240 of the poly-metal electrode structure 290 in a subsequent process. The fourth layer 240a may reduce or prevent the diffusion of impurities from the second layer 220a into the fifth layer during a process for forming the fifth layer 250a in FIG. 4E. For example, the fourth layer 240a may include a nitride layer including a refractory metal (e.g., a tungsten nitride (WN) layer, a titanium nitride (TiN) layer, a tantalum nitride (TaN) layer). The fourth layer 240a may include a metal nitride having the same metal as the fifth layer 250a or the metal silicide of the third layer 230a. Thus, when the fifth layer 250a includes a tungsten layer, the fourth layer 240a may include a tungsten nitride (WN) layer. When the third layer 230a includes a titanium silicide layer, the fourth layer 240a may include a titanium nitride layer. When the metal of the fourth layer 240a is substantially identical to a metal of the fifth layer 250a, the fourth layer 240a and the fifth layer 250a may be consecutively formed by a successive process. In addition, when the metal of the fourth layer 240a is substantially identical to a metal in a metal silicide of the third layer 230a, the third layer 230a and the fourth layer 240a may also be consecutively formed by a successive process.

A deposition process (e.g., a CVD process, an ALD process, a sputtering process) may be used where the fourth layer 240a includes tungsten nitride (WN). A processing chamber may be controlled to a temperature of about 200° C., and a mixture of argon (Ar) gas and nitrogen (N₂) gas may be provided into the processing chamber. A power of about 0.3 kW to about 1.2 kW may be supplied to the processing chamber at a pressure of about 1300 Pa. For example, a power of about 0.8 kW may be supplied to the processing chamber. As a result, plasma for sputtering a tungsten target may be generated in the processing chamber. Tungsten atoms sputtered from a tungsten target may react with activated nitrogen atoms because of the plasma on a surface of the third layer 230a, thereby forming the fourth layer 240a including tungsten nitride (WN). The fourth layer 240a may be formed to a thickness of about 10 Å to about 100 Å.

The supply of nitrogen gas may be stopped, such that only argon gas is provided into the processing chamber with a simultaneous power increase to the processing chamber. For example, electrical power of about 0.5 kW to about 1.6 kW (e.g., about 1.5 kW) may be supplied to the processing chamber while the argon gas is being provided. As shown in FIG. 4E, the fifth layer 250a including tungsten may be formed on the fourth layer 240a. The fifth layer 250a may be formed to a thickness of about 100 Å to about 1,000 Å.

The third layer 230a and the fourth layer 240a may be simultaneously formed in the same process where the fourth layer 240a includes titanium nitride (TiN). When a thermal treatment is performed on a titanium metal layer formed on the second layer 220a at a lower temperature, the titanium metal layer adjacent to the second layer 220a may be transformed into a titanium silicide layer by the thermal treatment, and the rest of the titanium metal layer may react with nitrogen (N₂) and, thus, become transformed into a titanium nitride layer. The heat-treatment performed at a lower temperature may accelerate the nitrification process, because ammonium (NH₃) gas or a mixture of ammonium (NH₃) gas and hydrogen (H₂) gas may be supplied to a thermal treatment conducted at a lower temperature. Thus, a lower portion of the titanium metal layer on the second layer 120a may be transformed into the titanium silicide layer, thereby forming the third layer 230a including titanium silicide. An upper portion of the titanium metal layer may be transformed into the titanium nitride layer by a nitrification process, thereby forming the fourth layer 240a including titanium nitride.

The fifth layer 250a may be formed on the fourth layer 240a by depositing a refractory metal using a sputtering process, a CVD process, a physical vapor deposition (PVD) process, or an ALD process. The refractory metal may include tungsten (W), titanium (Ti), tantalum (Ta), and other suitable metals. For example, the fifth layer 250a may include a tungsten layer formed by sputtering at a temperature of about 150° C., a pressure of about 4 mTorr, and a power of about 2 kW. The fifth layer 250a may be formed into a conductive metal layer 250 of the poly-metal electrode structure 290 by a subsequent process. The conductive metal layer 250 may include a refractory metal having a lower resistivity. The fifth layer 250a may be formed to a thickness of about 500 Å to about 1000 Å.

Referring to FIG. 4F, the fifth layer 250a, the fourth layer 240a, the third layer 230a, the second layer 220a, and the first layer 210a may be subsequently removed from the substrate 100 by a patterning process (e.g., a photolithography process) using a photoresist pattern (not shown) as an etching mask. As a result, the gate insulating layer 210, the polysilicon layer 220, the interface reaction preventing layer 230, the barrier layer 240, and the conductive metal layer 250 may be sequentially stacked on the substrate 100, thereby forming the gate electrode 200 on the substrate 100.

An ion implantation process may be performed on a surface of the substrate 100 using the gate electrode 200 as an ion implantation mask so as to form source/drain electrodes 300a and 300b doped with impurities at the surface of the substrate 100 adjacent to the gate electrode 200 as illustrated in FIG. 3. A channel region 400 may be formed under the gate electrode 200 between the source/drain electrodes 300a and 300b.

A spacer (not shown) may be further formed at a sidewall of the gate electrode 200 after forming the source/drain electrode 300a and 300b. When the spacers are formed at the sidewall of the gate electrode 200, an additional ion implantation process may be further performed on the surface of the substrate 100 using the spacer and the gate electrode 200 as an ion mask. As a result, the source/drain electrodes 300a and 300b may be formed into a lighter doped drain (LDD) structure having a lighter junction area and a heavier junction area.

Where the interface reaction preventing layer 230 includes a metal-rich metal silicide, an interfacial reaction between the interface reaction preventing layer 230 and the barrier layer 240 may be reduced or prevented during an etching process for forming the gate electrode 200, thus reducing or preventing the dissociation of the barrier layer 240. Accordingly, the thinning of the barrier layer 240 may be reduced or prevented despite the etching process to thereby sufficiently preserve the barrier characteristics of the barrier layer 240. In addition, the interface reaction preventing layer 230 may be formed at a relatively low temperature, and the formation process may be controlled with relative accuracy. As a result, the interface reaction preventing layer 230 may be formed on the polysilicon layer 220 to a relatively uniform thickness, and agglomeration and/or voids may be sufficiently reduced or prevented in the interface reaction preventing layer 230 to thereby improve the ohmic characteristic of the poly-metal electrode structure 290.

Tests on Characteristics of a Titanium-Rich Titanium Silicide Layer

For a titanium-rich titanium silicide (TiSiₓ)) layer to function as an interface reaction preventing layer 230 of a poly-metal electrode structure 290 according to example embodiments, it may be beneficial for the titanium-rich titanium silicide (TiSiₓ) layer to be relatively non-reactive with respect to the barrier layer 240 during a thermal treatment. It may also be beneficial for there to be a sufficiently small interface resistance between the barrier layer 240 and the titanium-rich titanium suicide (TiSiₓ) layer. Consequently, experiments were carried out to examine the characteristics of the titanium-rich titanium silicide (TiSiₓ) layer according to example embodiments.

1) Test on the Interface Resistance of the Titanium-Rich Titanium Silicide Layer

The interface reaction preventing layer 230 may be partially agglomerated when higher temperatures are applied during a thermal treatment process, thereby resulting in a higher interface resistance. The interface resistance of the interface reaction preventing layer 230 may affect the ohmic characteristic of the poly-metal electrode structure 290. Accordingly, experimental tests were conducted on the density of agglomerations to determine whether ohmic characteristics of the poly-metal electrode structure 290 may be improved by the interface reaction preventing layer 230 according to example embodiments.

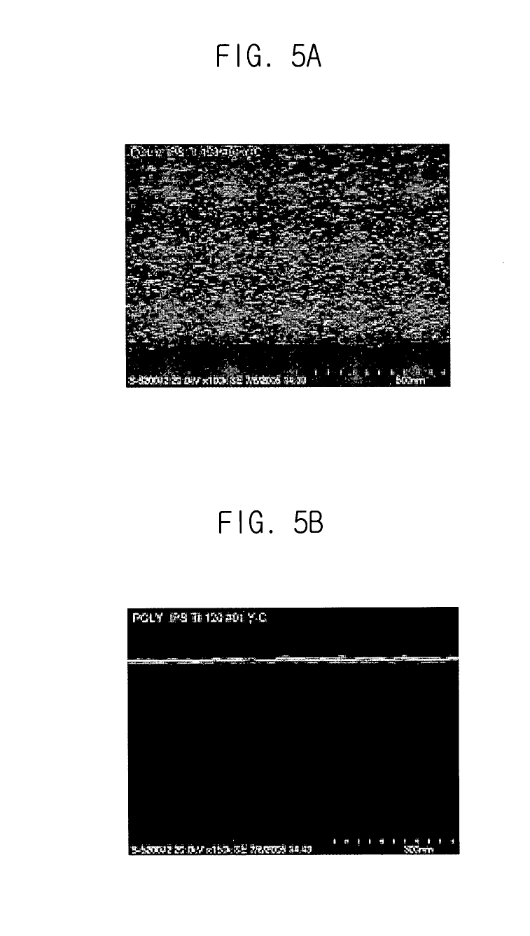

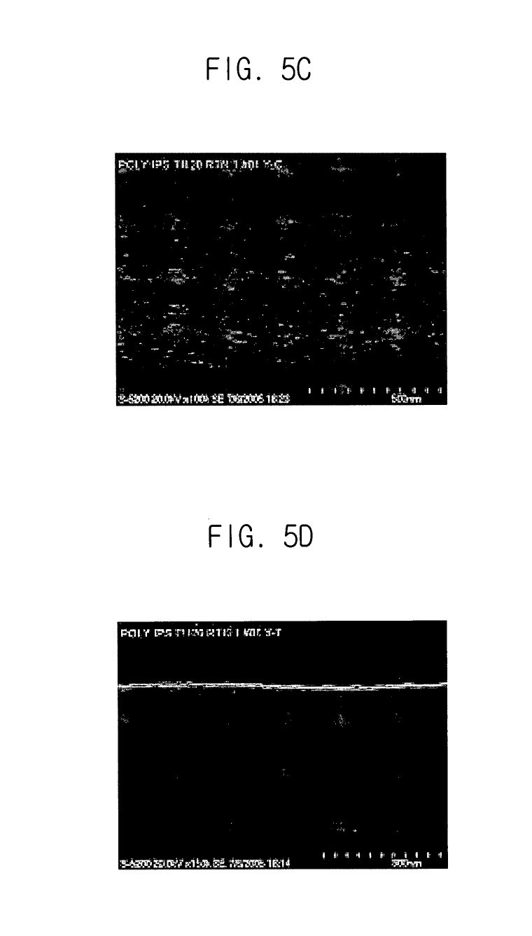

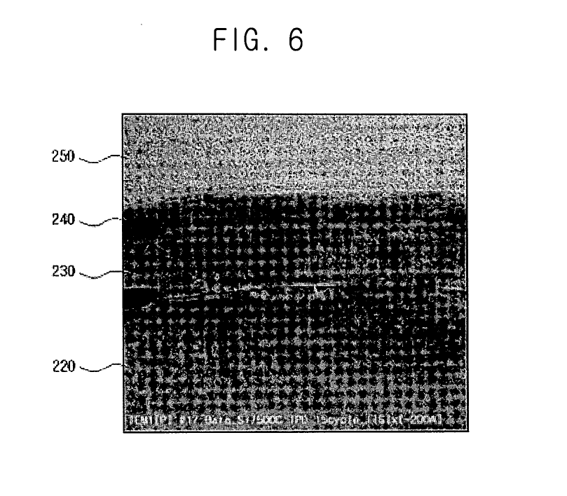

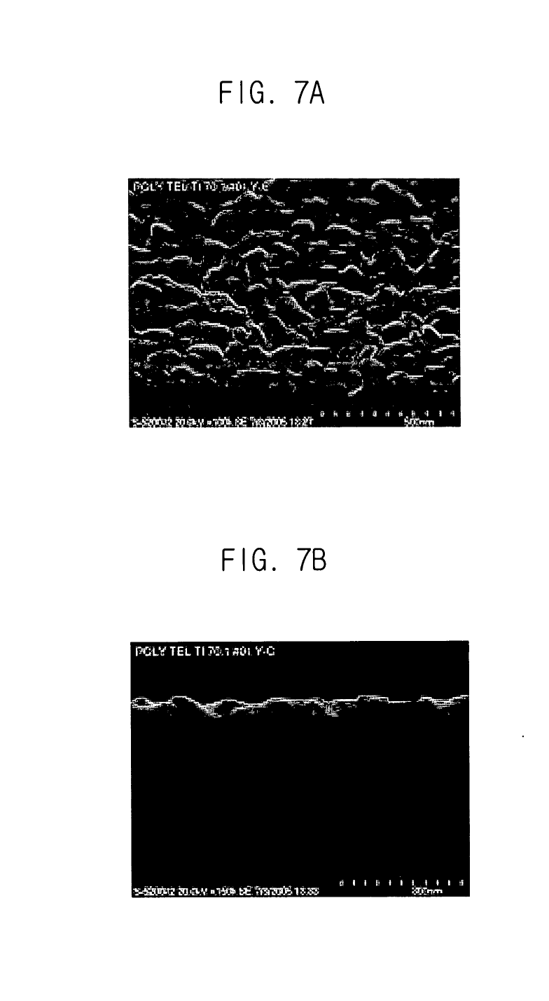

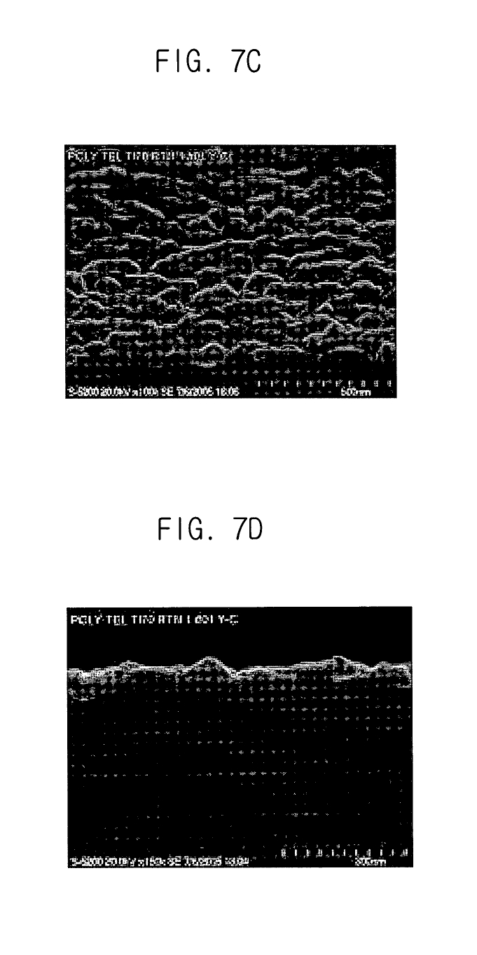

FIGS. 5A to 5D are scanning electron microscope (SEM) images showing the agglomeration density of a titanium-rich titanium silicide (TiSiₓ) layer formed in a lower temperature process. FIG. 6 is a transmission electron microscope (TEM) image showing a poly-metal electrode structure including the titanium-rich titanium silicide (TiSiₓ) layer. FIGS. 7A to 7D are SEM images showing the agglomeration density of a conventional titanium-rich titanium silicide (TiSiₓ) layer formed in a higher temperature process. The titanium-rich titanium silicide (TiSiₓ) layer in FIGS. 5A to 5D and FIG. 6 was formed at a lower temperature of about 530° C., while the titanium-rich titanium silicide (TiSiₓ) layer in FIGS. 7A to 7D was formed at a higher temperature of about 650° C. FIGS. 5A, 5B, 6, 7A, and 7B were taken by an SEM after formation of the titanium-rich titanium silicide (TiSiₓ)) layer, and the images in FIGS. 5C, 5D, 7C, and 7D were taken by an SEM after a rapid thermal treatment (RTP) in a nitrogen atmosphere. FIGS. 5A, 5C, 7A, and 7C are enlarged images of a surface of the titanium-rich titanium silicide (TiSiₓ) layer at a magnification of about one hundred thousand times, and FIGS. 5B, 5D, 7B, and 7D are enlarged images of a cross-section of the titanium-rich titanium silicide (TiSiₓ) layer.

A comparison of the images in FIGS. 5A to 5D and the images in FIGS. 7A to 7D shows that the agglomeration density of the lower-temperature titanium-rich titanium silicide (TiSiₓ) layer is lower than that of the higher-temperature titanium-rich titanium silicide (TiSiₓ) layer, thereby showing that agglomerations of a titanium-rich titanium silicide layer may be reduced by a lower temperature process. FIG. 5A shows an improvement over FIG. 7A as to agglomerations of the titanium-rich titanium silicide (TiSiₓ)) layer after depositing the titanium-rich titanium silicide (TiSiₓ) layer. The higher-temperature titanium-rich titanium silicide layer had a more agglomerated and irregular surface. In contrast, the lower-temperature titanium-rich titanium silicide (TiSiₓ) layer was less agglomerated and had a relatively flat surface.

Furthermore, a comparison of the images in FIGS. 5C and 7C indicate that the lower-temperature titanium-rich titanium silicide layer was less agglomerated than the higher-temperature titanium-rich titanium silicide layer after a thermal treatment was performed. The improvement on the degree of agglomeration may be observed in the comparison of the SEM images in FIGS. 5B and 7B and the SEM images in FIGS. 5D and 7D, which show the cross-sectional surface of the titanium-rich titanium suicide (TiSiₓ) layer. Referring to FIG. 5B, a top portion of the cross-sectional surface of the lower-temperature titanium-rich titanium silicide (TiSiₓ) layer appears relatively linear, thus showing that fewer agglomerations were on the surface of the lower-temperature titanium-rich titanium silicide (TiSiₓ) layer. In contrast, referring to FIG. 5D, a top portion of the cross-sectional surface of the higher-temperature titanium-rich titanium silicide (TiSiₓ) layer appears to have a plurality of concave and convex portions, thus showing that more agglomerations were on the surface of the higher-temperature titanium-rich titanium silicide (TiSiₓ) layer. As a result, the comparison of FIGS. 5B and 5D indicates that the uniformity of the titanium-rich titanium silicide layer may be improved by the lower temperature process.

A comparison of FIGS. 7B and 7D indicates that a higher temperature thermal treatment may have a lesser effect on the uniformity of a lower-temperature titanium-rich titanium silicide layer, while a higher temperature thermal treatment may have more of an effect on the uniformity of a higher-temperature titanium-rich titanium silicide layer. Accordingly, the experimental results show that the agglomeration degree of the lower-temperature titanium-rich titanium silicide layer was smaller than that of the higher-temperature titanium-rich titanium silicide layer. Thus, the uniformity of the lower-temperature titanium-rich titanium silicide layer is improved compared to that of the higher-temperature titanium-rich titanium silicide layer. Smaller agglomerations and/or increased uniformity of the lower-temperature titanium-rich titanium silicide layer may lead to an improvement of the interface resistance of the lower-temperature titanium-rich titanium silicide layer, thereby improving the ohmic characteristic of the poly-metal electrode structure 290 including the lower-temperature titanium-rich titanium silicide layer as the interface reaction preventing layer 230. The TEM image in FIG. 6 shows that the boundary portion between the polysilicon layer 220 and the interface reaction preventing layer 230 and the boundary portion of the interface reaction preventing 230 and the barrier layer 240 is relatively linear.

Further to the above experimental results, processing defects (e.g., agglomerations, voids) may be reduced or prevented in the lower-temperature titanium-rich titanium silicide (TiSix) layer according to example embodiments, thereby improving the omhic characteristic of the electrode structure including the lower-temperature titanium-rich titanium silicide layer.

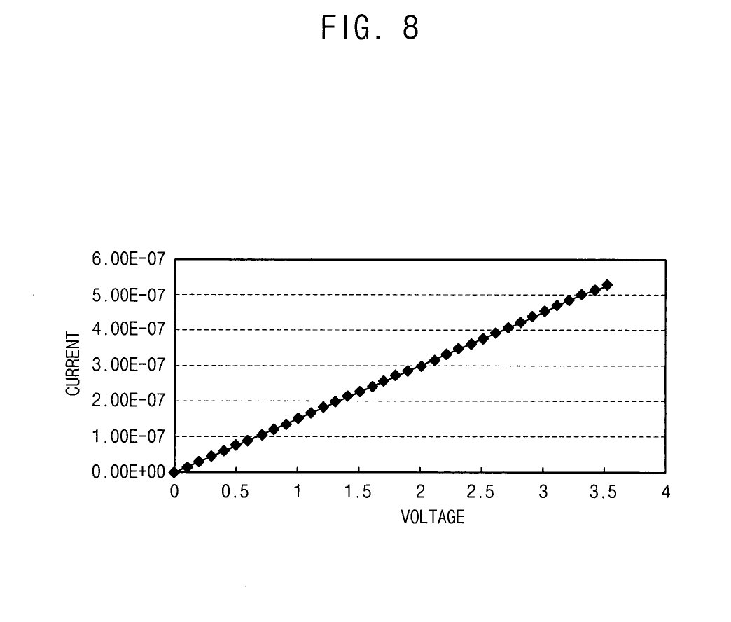

FIG. 8 is a graph illustrating the relationship between voltage and current of a poly-metal gate electrode including a titanium-rich titanium silicide (TiSiₓ) layer according to example embodiments. The graph in FIG. 8 results from a linear regression analysis using a least squares method to show the relationship between the currents independently measured at different voltages. Referring to FIG. 8, the current passing through the poly-metal gate electrode is linearly proportional to the applied voltage, and a coefficient of determination R₂ is about 1. Accordingly, there may be a stronger linearity at a higher reliability between the voltage and the current of the poly-metal gate electrode. Thus, the poly-metal gate electrode including the titanium-rich titanium silicide as the interface reaction preventing layer may have a stronger linearity at a higher reliability between the voltage and current thereof. As a result, the experimental results confirm that the lower-temperature titanium-rich titanium silicide according to example embodiments may improve the ohmic characteristic of the poly-metal gate electrode.

2) Test on the Reactivity of the Titanium-Rich Titanium Silicide Layer with the Barrier Layer

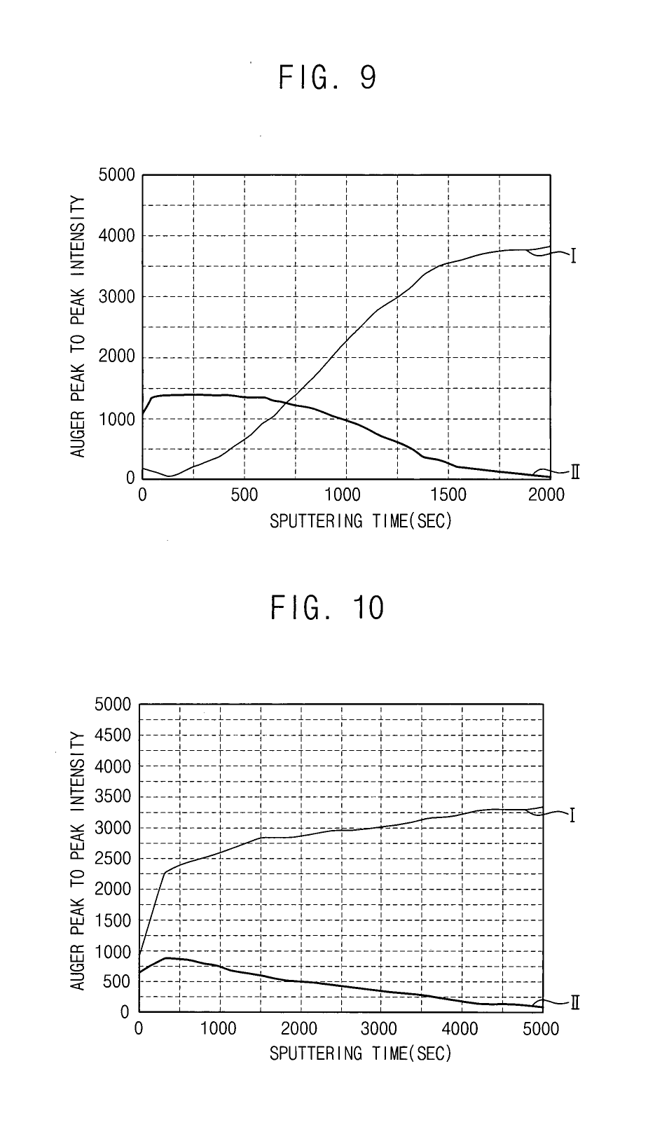

FIG. 9 is a graph showing analysis results of the lower-temperature titanium-rich titanium silicide (TiSiₓ) layer by an auger electron spectroscopy (AES). FIG. 10 is a graph showing analysis results of a conventional higher-temperature titanium-rich titanium silicide (TiSiₓ) layer by an auger electron spectroscopy (AES). In FIG. 9, the AES analysis was performed with respect to the titanium-rich titanium silicide (TiSiₓ) layer formed by a sputtering process at a lower temperature of about 530° C. In FIG. 10, the AES analysis was performed with respect to the titanium-rich titanium silicide (TiSiₓ) layer formed by a sputtering process at a higher temperature of about 650° C. In FIGS. 9 and 10, a horizontal axis represents a reaction time in the sputtering process, and a vertical axis represents a peak intensity of an auger electron (hereinafter, referred to as “an auger peak intensity”) of each element in the sputtering process. Graph I shows the auger peak intensity of silicon, and Graph II shows the auger peak intensity of titanium.

Referring to FIGS. 9 and 10, in the lower-temperature titanium-rich titanium silicide (TiSiₓ) layer, the auger peak intensity of the titanium is higher than the auger peak intensity of the silicon up to an initial reaction time of about 750 seconds after the sputtering process is performed. In contrast, in the conventional higher-temperature titanium silicide (TiSiₓ) layer, the auger peak intensity of the silicon is higher than the auger peak intensity of the titanium during the same initial reaction time. Accordingly, the graphs in FIGS. 9 and 10 show that the lower-temperature titanium-rich titanium silicide (TiSiₓ) layer may have a larger amount of titanium with respect to the silicon than the conventional higher-temperature titanium silicide (TiSiₓ) layer.

Table 2 shows thermodynamic simulation results on the reactivity of a titanium silicide (TiSiₓ) layer with a tungsten nitride (WN) layer in accordance with the mole ratio of titanium (Ti) and silicon (Si) in the titanium silicide (TiSiₓ) layer. The tungsten nitride (WN) layer may be provided on the titanium silicide (TiSiₓ) layer and may function as a barrier layer 240 in the poly-metal gate electrode 200.

TABLE 2

| | | | |
|---|---|---|---|
| Reactant | Ti₂Si + W | TiSi + W | TiSi₂ + W |
| (mole) | | | |
| Product | 1.00W | 0.33W | 0.57WSi₂ |
| (mole) | — | 0.13W₅Si₃ | 0.08W₅Si₃ |
| | 0.33Ti₅Si₃ | 0.20Ti₅Si₃ | 0.20Ti₅Si₃ |
| | 0.33Ti | | |
| Reaction Ratio of | 0% | 67% | 100% |
| Tungsten | | | |

As shown in Table 2, when a mole fraction of titanium is greater than the mole fraction of silicon in the titanium silicide (TiSiₓ) layer, the reaction of tungsten (W) in the tungsten nitride (WN) layer with silicon (Si) in the titanium silicide (TiSiₓ) layer is relatively low (if not nil), thereby reducing or preventing the generation of tungsten silicide (WSiₓ). In contrast, when a mole fraction of titanium is smaller than the mole fraction of silicon in the titanium silicide (TiSiₓ)) layer, all of the tungsten (W) in the tungsten nitride (WN) layer was reacted with silicon (Si) in the titanium silicide (TiSiₓ) layer, thereby generating tungsten silicide (WSiₓ). The simulation results also show that when the mole ratio of titanium to silicon is equal to or greater than about 2:1, the reaction of the titanium silicide (TiSiₓ) layer with the tungsten is relatively low (if not nil).

The titanium suicide layer according to example embodiments may include titanium-rich titanium silicide (TiSiₓ), wherein a mole fraction of titanium may be greater than the mole fraction of silicon. Thus, the reactivity of the titanium silicide (TiSiₓ) with the barrier layer 240 may be decreased, thereby reducing or preventing the dissociation of the barrier layer during a higher temperature thermal treatment. Therefore, the barrier characteristics of the barrier layer 240 may be preserved during a higher temperature thermal treatment.

The interface reaction preventing layer 230 of the poly-metal electrode structure 290 may include a metal-rich metal silicide, wherein the mole ratio of metal to silicon equal to or greater than about 1:1. Thus, the chemical reaction between the interface reaction preventing layer 230 and the barrier layer 240 may be reduced or prevented during a higher temperature thermal treatment to thereby reduce or prevent the dissociation of the barrier layer 240. Accordingly, the barrier characteristic of the barrier layer 240 may be preserved. In addition, the metal-rich metal silicide layer may be formed at a relatively low temperature of about 400° C. to about 600° C., thus enabling the formation process to be more efficiently controlled. Accordingly, the metal-rich metal silicide layer may be formed relatively uniformly on the surface of the polysilicon layer 220 with fewer processing defects (e.g., agglomerations, voids). Furthermore, the relative uniformity of the metal-rich metal silicide layer may be preserved not only after the deposition process but also after a higher temperature thermal treatment process. Thus, increased sheet resistance caused by agglomerations may be reduced or prevented. Therefore, the ohmic characteristics of the poly-metal electrode structure 290 may be improved.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A semiconductor device comprising:
a gate insulating layer on a semiconductor substrate;
a polysilicon layer on the gate insulating layer, the polysilicon layer doped with impurities;
an interface reaction preventing layer on the polysilicon layer, the interface reaction preventing layer including a metal-rich metal silicide having a metal mole fraction greater than a silicon mole fraction;
a barrier layer on the interface reaction preventing layer; and
a conductive metal layer on the barrier layer, the conductive metal layer including a refractory metal.

2. The semiconductor device of claim 1, wherein the barrier layer prevents the impurities doped in the polysilicon layer from diffusing into the conductive metal layer, and the interface reaction preventing layer prevents a chemical interfacial reaction with the barrier layer.

3. The semiconductor device of claim 1, wherein a mole ratio of metal to silicon in the metal-rich metal silicide is in a range of about 1:1 to about 4:1.

4. The semiconductor device of claim 1, wherein the metal silicide includes one of tungsten silicide, titanium silicide, and tantalum silicide.

5. The semiconductor device of claim 1, wherein the barrier layer includes a metal nitride layer having a refractory metal.

6. The semiconductor device of claim 5, wherein the metal nitride includes one of tungsten nitride, titanium nitride, and tantalum nitride.

7. The semiconductor device of claim 1, wherein the conductive metal layer includes one of a tungsten layer, a titanium layer, and a tantalum layer.

8. The semiconductor device of claim 1, further comprising:
source/drain regions doped with impurities at a surface of the substrate; and
a channel region at the surface of the substrate between the source/drain regions.

9. A method of manufacturing a semiconductor device, comprising:
forming a first layer on a semiconductor substrate;
forming a second layer doped with impurities on the first layer;
forming a third layer on the second layer, the third layer including a metal-rich metal silicide having a metal mole fraction greater than a silicon mole fraction;
forming a fourth layer on the third layer;
forming a fifth layer on the fourth layer, the fifth layer including a refractory metal; and
patterning the fifth layer, the fourth layer, the third layer, the second layer, and the first layer to form a gate electrode including a gate insulating layer, a polysilicon layer, an interface reaction preventing layer, a barrier layer, and a conductive metal layer on the semiconductor substrate.

10. The method of claim 9, wherein the barrier layer prevents the impurities doped in the polysilicon layer from diffusing into the conductive metal layer, and the interface reaction preventing layer prevents a chemical interfacial reaction with the barrier layer.

11. The method of claim 9, wherein the first layer is formed to a thickness of about 10 Å to about 100 Å by a thermal oxidation process.

12. The method of claim 9, wherein the second layer is formed to a thickness of about 500 Å to about 2000 Å by a chemical vapor deposition (CVD) process using a source gas including silane (SiH₄) gas and an impurities gas.

13. The method of claim 9, wherein forming the third layer comprises:
forming a dummy metal layer on the second layer; and
performing a thermal treatment on the dummy metal layer in a nitrogen atmosphere.

14. The method of claim 13, wherein the dummy metal layer is formed on the second layer by one of a sputtering process, a chemical vapor deposition process, and an atomic layer deposition process.

15. The method of claim 13, wherein the thermal treatment is performed at a temperature of about 400° C. to about 600° C. using ammonia (NH₃) gas or a mixture of ammonia (NH₃) gas and hydrogen (H₂) gas.

16. The method of claim 13, wherein a lower portion of the dummy metal layer contacting the second layer is transformed into a metal silicide by the thermal treatment to form the third layer, and an upper portion of the dummy metal layer is transformed into a metal nitride by the thermal treatment to form the fourth layer, such that the third layer and the fourth layer are simultaneously formed on the second layer.

17. The method of claim 9, wherein forming the third layer includes:
providing titanium chloride (TiCl₄) gas and hydrogen (H₂) gas to a processing chamber having a pressure of about 0.5 Torr to about 10 Torr and a temperature of about 400° C. to about 600° C.; and
providing the titanium chloride (TiCl₄) gas and hydrogen (H₂) gas onto the second layer by a chemical vapor deposition process to form a titanium silicide layer on the second layer.

18. The method of claim 9, wherein forming the third layer includes forming a metal silicide layer on the second layer by an atomic layer deposition process using a metal precursor and hydrogen (H₂) gas as a reaction gas at a temperature of about 400° C. to about 600° C.

19. The method of claim 9, wherein forming the third layer includes:
forming a dummy metal layer on the second layer by a chemical vapor deposition process using a metal precursor and hydrogen (H₂) gas at a temperature of about 400° C. to about 600° C.; and
performing a hydrogen (H₂) plasma treatment or an ammonia (NH₃) plasma treatment on the dummy metal layer to transform the dummy metal layer into a metal silicide layer.

20. The method of claim 9, wherein forming the third layer includes forming a metal silicide layer on the second layer by an atomic layer deposition process using a metal precursor and silane (SiH₄) gas as a reaction gas at a temperature of about 400° C. to about 600° C.

21. The method of claim 9, wherein a mole ratio of metal with respect to silicon in the metal-rich metal silicide is in a range of about 1:1 to about 4:1.

22. The method of claim 9, wherein the metal silicide includes at least one metal selected from the group consisting of tungsten, titanium, and tantalum.

23. The method of claim 9, wherein the third layer is formed to a thickness of about 10 Å to about 50 Å.

24. The method of claim 9, wherein forming the fourth layer includes:
providing argon (Ar) gas and nitrogen gas to a processing chamber containing a target metal and the substrate having the third layer;
generating plasma in the processing chamber; and
forming a metal nitride layer on the third layer by a chemical reaction between nitrogen atoms of the nitrogen gas activated by the plasma and metal atoms sputtered from the target metal by the plasma.

25. The method of claim 24, wherein the target metal includes one of tungsten, titanium, and tantalum.

26. The method of claim 24, wherein generating the plasma includes supplying electrical power of about 0.3 kW to about 1.2 kW to the processing chamber.

27. The method of claim 26, further comprising:
removing the nitrogen gas from the processing chamber; and
increasing the electrical power supplied to the processing chamber to about 0.5 kW to about 1.6 kW to form the fifth layer on the fourth layer.

28. The method of claim 9, wherein forming the fourth layer includes forming a metal nitride layer on the third layer by a chemical vapor deposition process or an atomic layer deposition process.

29. The method of claim 28, wherein the metal nitride layer includes one of a tungsten nitride layer, a titanium nitride layer, and a tantalum nitride layer.

30. The method of claim 9, wherein the fourth layer is formed to a thickness of about 10 Å to about 100 Å.

31. The method of claim 9, wherein forming the fifth layer includes depositing a refractory metal on the fourth layer by one of a sputtering process, a chemical vapor deposition process, a physical vapor deposition process, and an atomic layer deposition process.

32. The method of claim 31, wherein the refractory metal includes at least one of tungsten, titanium, and tantalum.

33. The method of claim 9, further comprising:
forming source/drain regions on a surface of the substrate adjacent to the gate electrode by injecting impurities onto the surface of the substrate by an ion implantation process using the gate electrode as an ion implantation mask.
